(19) United States
(12) Patent Application Publication
(10) Pub. No.: US 2026/0280224 A1
(43) Pub. Date: Sep. 17, 2026

(54) LASER MODULE, OPTICAL ENGINE, AND XR GLASSES

(71) Applicant: TDK Corporation, Tokyo (JP)

(72) Inventor: Yusuke SHIGETA, Tokyo (JP)

(73) Assignee: TDK Corporation, Tokyo (JP)

(21) Appl. No.: 19/541,521

(22) Filed: Feb. 17, 2026

(30) Foreign Application Priority Data
Mar. 17, 2025 (JP) 2025-042206

(51) Int. Cl. H01S 5/02326; G02B 6/00; H01S 5/02325; H01S 5/40

(52) U.S. Cl. CPC H01S 5/02326; G02B 6/00; H01S 5/02325; H01S 5/4012

(57) ABSTRACT

The laser module 1000 includes, in a package 110, a plurality of subcarriers 20, a plurality of laser elements 30 mounted on the main surfaces of the plurality of subcarriers 20, and an optical waveguide substrate 40 having an optical waveguide layer 50 on its main surface, the optical waveguide layer 50 having an optical waveguide 51 for guiding the laser light respectively emitted from the plurality of laser elements 30. A getter material 60 for adsorbing volatile organic compounds is disposed on the upper surface of the optical waveguide layer 50 near the incident surface of the optical waveguide layer 50 where the laser light is incident.

### CROSS-REFERENCE TO RELATED APPLICATION

This application claims a priority, under the Paris Convention, to Japanese Patent Application No. 2025-042206 filed on Mar. 17, 2025, the entirety of which is incorporated herein by reference.

### TECHNICAL FIELD

The present disclosure relates to a laser module, an optical engine, and XR glasses.

### BACKGROUND

XR glasses, such as AR (Augmented Reality) glasses and VR (Virtual Reality) glasses, are expected to be small wearable devices. The key to the widespread use of wearable devices such as AR glasses and VR glasses is to miniaturize them so that each function fits into the size of a normal pair of glasses.

International Publication No. WO 2021/149450 discloses an integrated optical device that is miniaturized by bonding a base that holds a laser element and a substrate on which an optical waveguide is provided on the surface with the light emission position of the laser element and the position of the optical waveguide precisely aligned via a metal layer.

FIG. 13 is a schematic plan view illustrating the integrated optical device disclosed in WO 2021/149450. FIG. 14 is a schematic cross-sectional view of the integrated optical device shown in FIG. 13 taken along line A-A′. The reference numerals in the drawings correspond to the reference numerals of the components of the laser module of this embodiment, which will be described later, and the components necessary for the explanation will be described here.

The integrated optical device shown in FIGS. 13 and 14 comprises a plurality of laser elements 30 (30-1, 30-2, 30-3), each of which is mounted on a main surface 21 (21-1, 21-2, 21-3), a plurality of individual subcarriers 20 (20-1, 20-2, 20-3) spaced apart from one another, an optical waveguide layer 50 having an optical waveguide 51 that guides the laser light emitted from the laser elements 30 (30-1, 30-2, 30-3), an optical waveguide substrate 40 on whose surface the optical waveguide layer 50 is provided, and a metal film 70 that bonds the subcarriers 20 (20-1, 20-2, 20-3) to the optical waveguide substrate 40.

As recognized by the present inventor, however, the integrated optical device disclosed in WO 2021/149450 is concerned that the optical output power will decrease due to the accumulation of volatile organic compounds (VOCs) due to the dust collection effect at the emission part of the laser element.

### SUMMARY

One aspect of the present disclosure provides a laser module that includes, in a package, a plurality of laser element bases, a plurality of laser elements mounted on the respective main surfaces of the plurality of laser element bases, and an optical waveguide substrate having an optical waveguide layer on its main surface. The optical waveguide layer includes an optical waveguide for guiding the laser light emitted from the plurality of laser elements. A first getter material that adsorbs volatile organic compounds is disposed on the upper surface of the optical waveguide layer near the incident surface of the optical waveguide layer where the laser light is incident.

One aspect of the present disclosure provides an optical engine that includes the laser module and an optical scanning mirror that scans the light emitted from the laser module.

One aspect of the present disclosure provides an XR glasses that includes the optical engine.

### BRIEF DESCRIPTION OF DRAWINGS

FIG. 1 shows a schematic plan view of a laser assembly provided in a laser module according to an embodiment of the present disclosure.

FIG. 2 shows a schematic cross-sectional view of the laser assembly shown in FIG. 1 taken along line A-A′.

FIG. 3A shows a schematic perspective view of a laser element base.

FIG. 3B shows a schematic cross-sectional view of an optical waveguide substrate.

FIG. 4 shows a schematic plan view showing another example (part 1) of the arrangement of getter material in a laser assembly according to an embodiment of the present disclosure.

FIG. 5 shows a schematic plan view showing another example (part 2) of the arrangement of getter material in a laser assembly according to an embodiment of the present disclosure.

FIG. 6 shows a schematic cross-sectional view of the laser assembly shown in FIG. 5 taken along line B-B′.

FIG. 7 shows a schematic plan view showing another example (part 3) of the arrangement of getter material in a laser assembly according to an embodiment of the present disclosure.

FIG. 8 shows a schematic plan view of a laser module according to an embodiment of the present disclosure.

FIG. 9 shows a schematic cross-sectional view of the laser module shown in FIG. 8 cut along the X-Z plane.

FIG. 10 shows a plan view of the laser module shown in FIG. 8 with the cover removed.

FIG. 11 shows a conceptual diagram for explaining XR glasses according to an embodiment of the present disclosure.

FIG. 12 shows a conceptual diagram showing how an image is projected directly onto the retina by laser light emitted from a laser module according to an embodiment of the present disclosure.

FIG. 13 shows a schematic plan view of a portion of a conventional integrated optical device.

FIG. 14 shows a schematic cross-sectional view of the integrated optical device shown in FIG. 13 cut along line A-A′.

### DETAILED DESCRIPTION

One aspect of the present disclosure provides a laser module, optical engine, and XR glasses that can effectively remove VOCs and suppress stray light.

Below, embodiments of the laser module, optical engine, and XR glasses according to the present disclosure will be described with reference to the drawings. Note that the dimensional ratios of the components in each drawing do not necessarily match the actual dimensional ratios.

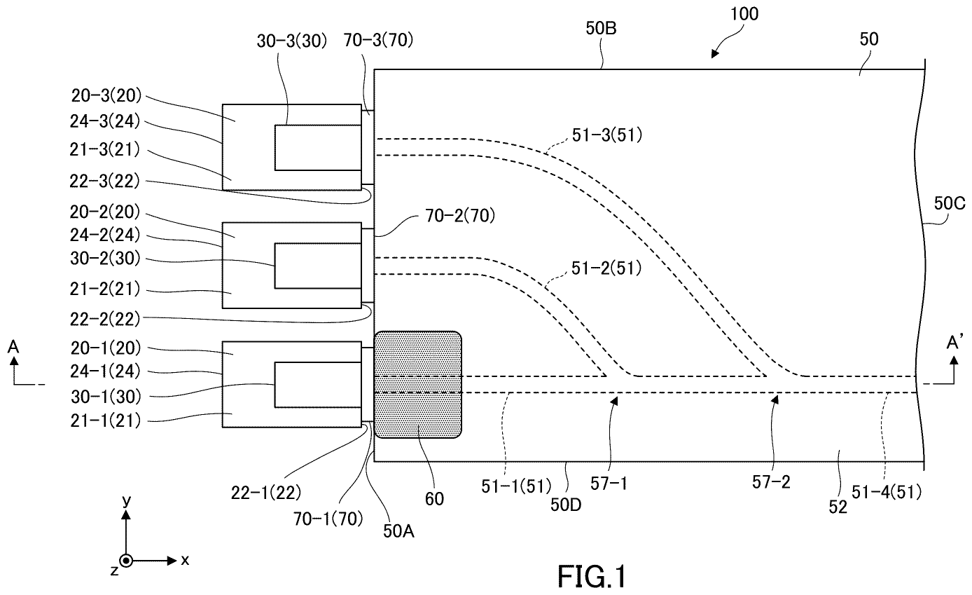

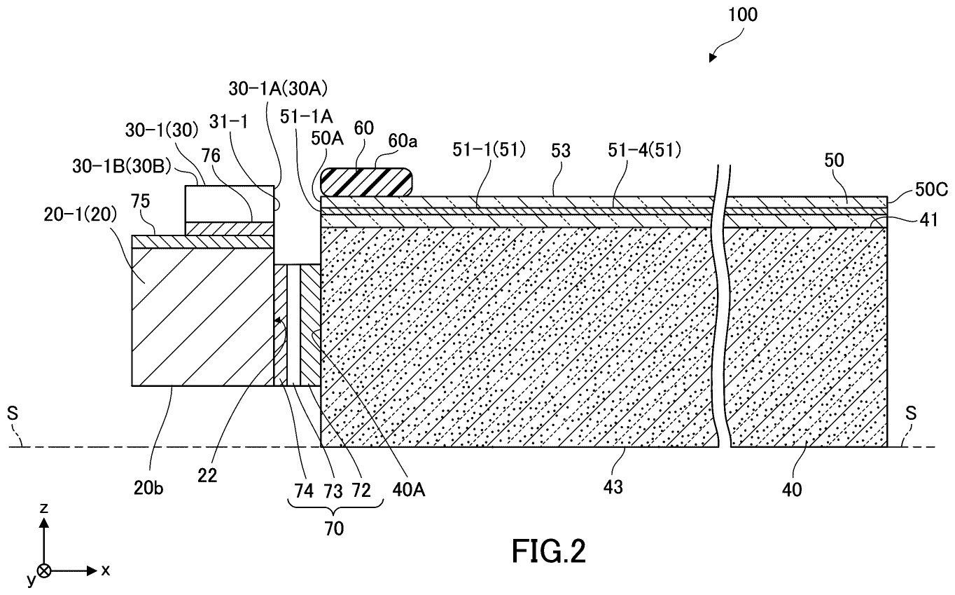

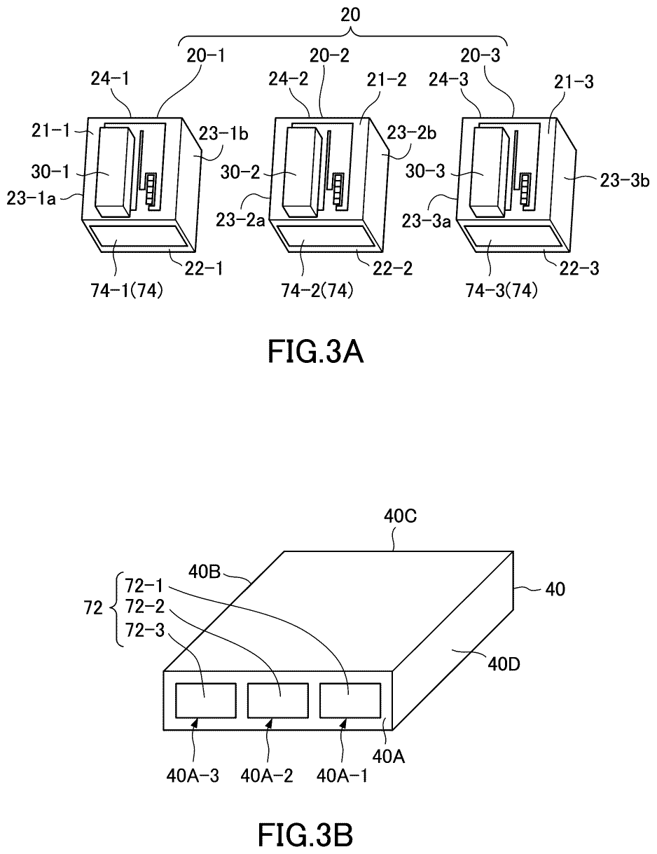

FIG. 1 is a schematic plan view of a portion of a laser assembly provided in a laser module according to this embodiment. FIG. 2 is a schematic cross-sectional view of the laser assembly shown in FIG. 1 taken along line A-A′. FIG. 3A is a schematic perspective view of a laser element base, and FIG. 3B is a schematic perspective view of an optical waveguide substrate.

The laser assembly 100 shown in FIG. 1 and FIG. 2 includes a plurality of laser element bases (hereinafter also referred to as “subcarriers”) 20 (20-1, 20-2, 20-3), a plurality of laser elements 30 (30-1, 30-2, 30-3) mounted on the respective main surfaces 21 (21-1, 21-2, 21-3) of the plurality of subcarriers 20, an optical waveguide substrate 40, an optical waveguide layer 50 provided on the main surface 41 of the optical waveguide substrate 40, and a getter material 60 disposed on the upper surface 53 of the optical waveguide layer.

Various laser elements can be used as the laser element 30. For example, commercially available laser diodes (hereinafter also referred to as “LDs”) for red, green, blue, near-infrared, ultraviolet, etc. can be used. For red light (R), light with a peak wavelength of 630 nm or more and 830 nm or less can be used. For green light (G), light with a peak wavelength of 500 nm or more and 550 nm or less can be used. For blue light (B), light with a peak wavelength of 380 nm or more and 500 nm or less can be used. For near-infrared light, light with a peak wavelength of 830 nm or more and 2000 nm or less can be used.

In the laser assembly 100 shown in FIG. 1, the laser elements 30-1, 30-2, and 30-3 are described as an LD that emits blue laser light, an LD that emits green laser light, and an LD that emits red laser light, respectively, for the sake of convenience. Hereinafter, the laser element 30-1 is also called the blue laser element 30-1, the laser element 30-2 is also called the green laser element 30-2, and the laser element 30-3 is also called the red laser element 30-3.

The laser elements 30-1, 30-2, and 30-3 can be mounted on individual subcarriers 20-1, 20-2, and 20-3, for example, as bare chips (chips that are not packaged). The number of laser elements shown in FIG. 1 is three, but this is just an example, and any number of multiples can be used.

The subcarriers 20-1, 20-2, and 20-3 are rectangular parallelepipeds, and have a flat main surface 21 (21-1, 21-2, and 21-3), a bonding surface 22 (22-1, 22-2, and 22-3) that is a flat surface perpendicular to the main surface 21, side surfaces 23 (23-1a, 23-1b, 23-2a, 23-2b, 23-3a, and 23-3b) that are flat surfaces perpendicular to the main surface 21 and the bonding surface 22, and an end surface 24 (24-1, 24-2, and 24-3) that is a flat surface opposite the bonding surface 22.

The subcarriers 20-1, 20-2, and 20-3 are made of, for example, aluminum nitride (AlN), aluminum oxide (Al₂O₃), silicon (Si), or the like.

Metal films 75, 76 are provided between the subcarrier 20 and the laser element 30 (see FIG. 2). The subcarrier 20 and the laser element 30 are connected via the metal films 75, 76. The method for forming the metal films 75, 76 can be any known method, but it is not particularly important to use known methods such as sputtering, vapor deposition, and application of a metal paste. The metal films 75 and 76 may contain one or more metals selected from the group consisting of gold (Au), platinum (Pt), silver (Ag), lead (Pb), indium (In), nickel (Ni), titanium (Ti) and tantalum (Ta), tungsten (W), an alloy of gold (Au) and tin (Sn), tin (Sn)-silver (Ag)-copper (Cu) solder alloy (SAC), SnCu, InBi, SnPdAg, SnBiIn, and PbBiIn, and may be made of one or more metals selected from this group.

The optical waveguide layer 50 has at least an optical waveguide that guides the laser light emitted from the laser element. There are no particular restrictions on this optical waveguide layer, and any known configuration can be used. The following shows an example of an optical waveguide layer.

The optical waveguide layer 50 has four end faces 50A, 50B, 50C, and 50D. The optical waveguide layer 50 shown in FIG. 1 is a rectangle with four 90° corners in a plan view (as viewed from the z direction), but is not limited to a rectangle with four 90° corners. Hereinafter, the end face 50A is also called the incident surface 50A, the end faces 50B and 50D are also called the side surfaces 50B and 50D, respectively, and the end face 50C is also called the emission surface 50C.

The optical waveguide layer 50 is a layer that performs the function of a PLC (Planar Lightwave Circuit). In addition, the optical waveguides 51 (51-1, 51-2, 51-3, 51-4) correspond to the cores in an optical fiber.

The optical waveguide layer 50 is formed on the optical waveguide substrate 40, and as described above, the laser element 30 is mounted on the subcarrier 20.

The optical waveguide substrate 40 has four end faces 40A, 40B, 40C, and 40D. In FIG. 1, the optical waveguide substrate 40 is a rectangle with four 90° corners that overlap with the optical waveguide layer 50 in a plan view (as viewed from the z direction), but is not limited to a rectangle with four 90° corners. Hereinafter, the end face 40A is also referred to as the bonding surface 40A, and the end faces 40B and 40D are also referred to as the side surfaces 40B and 40D, respectively.

The optical waveguide substrate 40 and the subcarrier 20 are integrated by eutectic bonding. This eutectic bonding enables accurate optical axis positioning and also realizes miniaturization.

The optical waveguide substrate 40 is made of, for example, silicon (Si). The optical waveguide layer 50 is fabricated on the main surface 41 so as to be integrated with the optical waveguide substrate 40 by a semiconductor process including known photolithography and dry etching used for forming fine structures such as integrated circuits.

As shown in FIG. 1, the optical waveguide layer 50 is provided with the same number of optical waveguides 51-1, 51-2, and 51-3 as the laser elements 30-1, 30-2, and 30-3, an optical waveguide 51-4 where the optical waveguides 51-1, 51-2, and 51-3 merge, and a cladding 52 surrounding the optical waveguides 51-1, 51-2, 51-3, and 51-4. The thickness of the cladding 52 and the width of the optical waveguides 51-1, 51-2, 51-3, and 51-4 are not particularly limited. For example, the optical waveguides 51-1, 51-2, 51-3, and 51-4, each having a width of about several microns, are disposed in the cladding 52, which has a thickness of about 50 μm.

The optical waveguides 51-1, 51-2, 51-3, and 51-4 and the cladding 52 are made of, for example, a glass material (e.g., quartz glass). In this case, the optical waveguide layer 50 is sometimes called a quartz-based PLC. The refractive index of the optical waveguides 51-1, 51-2, 51-3, and 51-4 is higher than the refractive index of the cladding 52 by a predetermined value. As a result, the light incident on each of the optical waveguides 51-1, 51-2, 51-3, and 51-4 propagates through each optical waveguide while being totally reflected at the interface between each optical waveguide and the cladding 52. The optical waveguides 51-1, 51-2, 51-3, and 51-4 are doped with an impurity such as germanium (Ge) in an amount corresponding to the above-mentioned predetermined value.

As shown in FIG. 1, the optical waveguides 51-1, 51-2, and 51-3 are gathered together just before reaching the emission surface 50C of the optical waveguide layer 50. That is, the optical waveguides 51-1, 51-2, and 51-3 merge sequentially as they move forward in the x-direction, and merge into one optical waveguide 51-4. The optical waveguide 51-4 reaches the emission surface 50C.

By eutectic bonding between the optical waveguide substrate 40 and the subcarrier 20, the optical axes of the optical waveguides 51-1, 51-2, and 51-3 in the optical waveguide layer 50 are precisely aligned so that the centers of the entrances of the optical waveguides 51-1, 51-2, and 51-3 are almost aligned with the optical axes of the emitted light from the corresponding laser elements 30-1, 30-2, and 30-3.

As shown in FIG. 2, the optical waveguide substrate 40 and the subcarrier 20 are arranged so that the incident surface 50A of the optical waveguide layer 50 faces the emission surface 30A (30-1A) of the laser element 30. In detail, the exit port 31-1 of the laser element 30-1 faces the entrance port 51-1A of the optical waveguide 51-1. In the y and z directions, the optical axis of the blue light emitted from the laser element 30-1 and the center of the entrance port 51-1A are approximately overlapped. Similarly, the exit port of the laser element 30-2 faces the entrance port of the optical waveguide 51-2. In the y and z directions, the optical axis of the green light emitted from the laser element 30-2 and the center of the entrance port are approximately overlapped. The exit port of the laser element 30-3 faces the entrance port of the optical waveguide 51-3. In the y and z directions, the optical axis of the red light emitted from the laser element 30-3 and the center of the entrance are approximately overlapped.

As shown in FIG. 1, the blue light, green light, and red light emitted from the laser elements 30-1, 30-2, and 30-3 are incident on the optical waveguides 51-1, 51-2, and 51-3, respectively, and then propagate through each optical waveguide. The blue light and green light propagating through the optical waveguides 51-1 and 51-2 are combined at a combining position 57-1. The combined blue light and green light and the red light propagating through the optical waveguide 51-3 are combined at a combining position 57-2. The RGB light combined at the combining position 57-2 propagates through the optical waveguide 51-4, reaches the emission surface 50C, and is emitted from the emission surface 50C.

In order to prevent light leakage from the optical waveguides 51-1, 51-2, and 51-3, it is preferable that the optical waveguides 51-1, 51-2, and 51-3 are each connected to the optical waveguide 51-4 with a curvature radius equal to or greater than a predetermined radius of curvature.

The optical waveguides 51-1, 51-2, 51-3, and 51-4 may be made of a lithium niobate film (LiNbO₃). In this case, the optical waveguide substrate 40 may be, for example, a sapphire substrate, a Si substrate, or a thermally oxidized silicon substrate.

The bonding surfaces 22 (22-1, 22-2, 22-3) of the individual subcarriers 20-1, 20-2, 20-3 and the bonding surface 40A (40A-1, 40A-2, 40A-3) of the optical waveguide substrate 40 are joined via multiple metal films 70 (70-1, 70-2, 70-3).

The metal film 70 is disposed between each of the bonding surfaces 22-1, 22-2, 22-3 of the individual subcarriers 20-1, 20-2, 20-3 and the multiple bonding surfaces 40A (40A-1, 40A-2, 40A-3) of the optical waveguide substrate 40 that correspond to the bonding surfaces 22-1, 22-2, 22-3 and are spaced apart from one another.

The metal film 70 is not a continuously formed film, but is disposed only on the bonding surfaces 40A-1, 40A-2, 40A-3 that are spaced apart from one another, and is an electrically and spatially separated film, which suppresses the occurrence of capacitive coupling and crosstalk.

For convenience, the metal film 70 shown in FIG. 2 is drawn as a three-layer structure, reflecting the manufacturing process of the metal film 70 (or the bonding process between the subcarrier and the optical waveguide substrate).

In addition, when explaining the metal film 70, each of the three layers may be explained.

That is, for the sake of convenience, the metal film 70 is depicted as consisting of three layers: a first metal film 74 (74-1, 74-2, 74-3) disposed on each of the bonding surfaces 22-1, 22-2, 22-3 of the individual subcarriers 20-1, 20-2, 20-3; a second metal film 72 (72-1, 72-2, 72-3) disposed on a plurality of bonding surfaces 40A-1, 40A-2, 40A-3 of the optical waveguide substrate 40 that correspond to the bonding surfaces 22-1, 22-2, 22-3, and that are spaced apart from each other; and a eutectic layer 73 disposed between the first metal film 74 and the second metal film 72. A preferred eutectic bonding using the eutectic layer 73 is Au—Sn bonding.

In actual bonding, if the first metal film and the second metal film are sufficiently thin, an alloy layer (eutectic layer) is formed, and the first metal film and the second metal film do not remain. On the other hand, if either the first metal film or the second metal film is thick, only the surface side of the thick metal film may become eutectic, leaving the part on the subcarrier side or the optical waveguide substrate side, and the other metal film may become entirely eutectic, but it becomes difficult to distinguish them as clear layers (distinguishing the interface).

In this way, in actual bonding, the film structure of the metal film 70 will differ depending on the conditions of the manufacturing process of the metal film 70, and the drawings are a conceptual depiction of the characteristic aspects of the film structure.

For example, a structure in which one or both of the first metal film 74 and the second metal film 72 remain relatively intact, or a structure in which the first metal film 74 and the second metal film 72 are entirely alloyed to form a eutectic layer may be obtained.

The second metal film 72 disposed on the bonding surfaces 40A-1, 40A-2, and 40A-3 is preferably made of Sn or an alloy containing Sn, such as Sn—Ag—Cu (SAC).

The first metal film 74 disposed on the bonding surfaces 22-1, 22-2, and 22-3 is preferably a metal capable of forming a eutectic with Sn, and may be, for example, one selected from the group consisting of Au, Si, Al, Ni, Pb, Zn, and Pt, or an alloy thereof, but is more preferably made of Au or an alloy containing Au.

The getter material 60 is disposed on the upper surface 53 of the optical waveguide layer 50 near the incident surface 50A of the optical waveguide layer 50 on which the laser light emitted from at least one of the laser elements 30-1, 30-2, and 30-3 is incident. The thickness of the getter material 60 is, for example, 100 μm or more and 300 μm or less.

The getter material 60 is, for example, a resin or metal material capable of adsorbing VOCs remaining or generated in the laser module after sealing, which will be described later. The getter material 60 may be capable of adsorbing not only VOCs but also moisture. As the getter material 60, it is preferable to use a material capable of adsorbing SiO and hydrocarbons, among VOCs, in particular, in a form that can be applied to the upper surface 53 and the side surfaces 50B and 50D of the optical waveguide layer 50 using a dispenser or the like.

The resin getter material that can be used as the getter material 60 is, for example, an epoxy-based material such as a glycidyl ether of a phenol-formaldehyde polymer (Phenol-Formaldehyde Polymer Glycidyl Ether). Specifically, as a resin getter material that adsorbs moisture, “Zedry/M” manufactured by SAES can be used. As a resin getter material that adsorbs VOCs such as SiO and hydrocarbons, “Zedry/VOC” manufactured by SAES can be used. In addition, the metal getter material that can be used as the getter material 60 may be, for example, a paste of metals such as Al, Ti, V, Cr, Mn, Fe, Co, Ni, Zr, Nb, Hf, Ta, Pt, and Au, or a paste of an alloy of these metals.

FIG. 1 shows an example in which the getter material 60 is disposed only in front of the blue laser element 30-1 on the upper surface 53 of the optical waveguide layer 50. Compared to the green laser element 30-2 and the red laser element 30-3, the blue laser element 30-1 is more susceptible to VOCs and moisture and its emission intensity is reduced, so it is desirable to dispose the getter material 60 at least in the vicinity of the blue laser element 30-1.

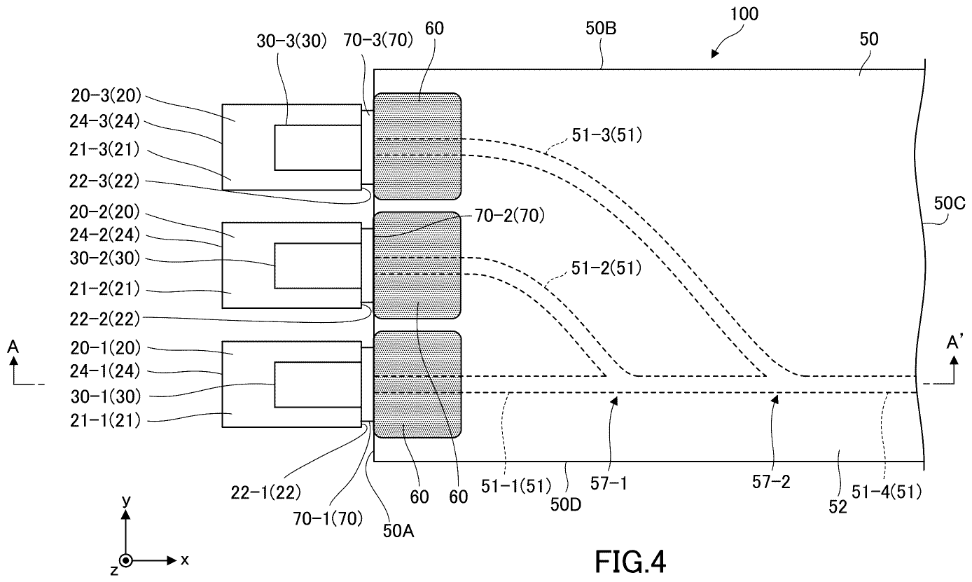

The present disclosure is not limited to the example shown in FIG. 1, and the getter material 60 may be disposed individually in front of the green laser element 30-2 and the red laser element 30-3 on the upper surface 53 of the optical waveguide layer 50. For example, as shown in FIG. 4, the getter material 60 may be disposed individually in front of all the laser elements 30-1, 30-2, and 30-3 on the upper surface 53 of the optical waveguide layer 50, while being mechanically separated from each other.

In this way, by selectively disposing the getter material 60 near each laser element 30 as necessary, the amount of getter material 60 used can be reduced.

As shown in FIG. 2, it is desirable to dispose the getter material 60 near the front of the laser element 30 (30-1) so as to block a portion of the laser light emitted from the laser element 30 (30-1) that has not entered the optical waveguide 51 of the optical waveguide layer 50. Specifically, the getter material 60 is disposed so that the height of the upper surface 60a of the getter material 60 is higher than the height of the upper surface 30B (30-1B) of the laser element 30 (30-1). The getter material 60 may be disposed similarly for the laser elements 30-2 and 30-3. This maximizes the VOC adsorption effect of the getter material 60, and prevents laser light that is not incident on the optical waveguide 51 of the optical waveguide layer 50 from becoming stray light within the laser module.

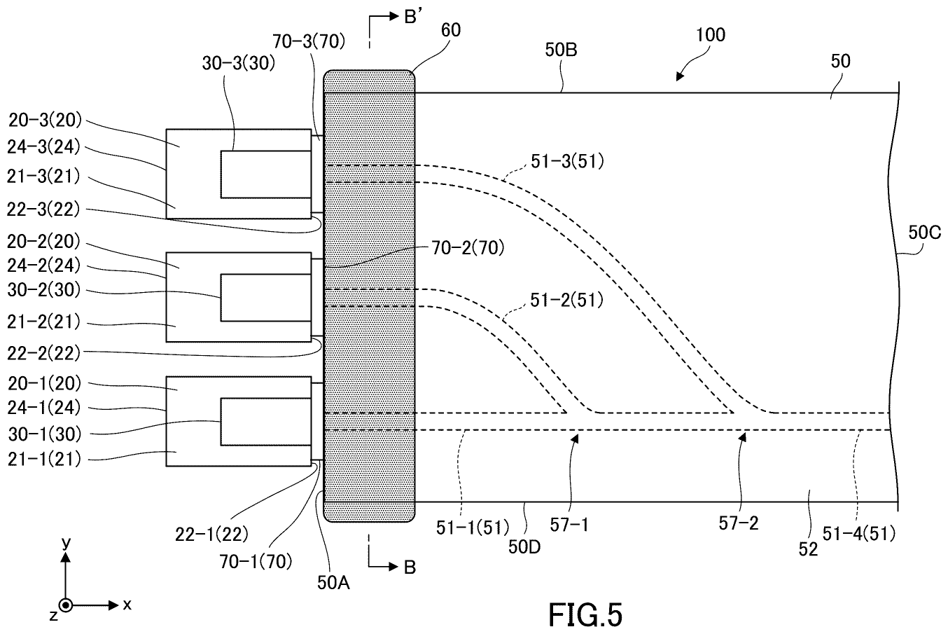

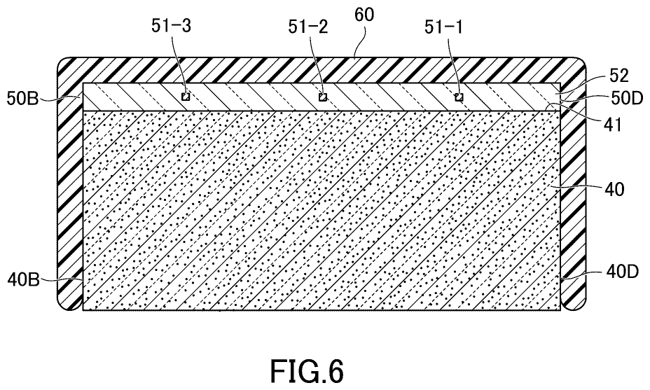

FIG. 5 is a schematic plan view of a portion of a laser assembly showing another arrangement example of the getter material 60. FIG. 6 is a schematic cross-sectional view of the laser assembly shown in FIG. 5 taken along line B-B′.

As shown in FIGS. 5 and 6, the getter material 60 may be arranged to cover a portion of the upper surface 53 and portions of the side surfaces 50B and 50D of the optical waveguide layer 50, and a portion of the side surfaces 40B and 40D of the optical waveguide substrate 40 in a U-shape. The U-shaped getter material 60 can suppress the expansion and contraction in the y direction of the portion of the getter material 60 located on the upper surface 53 of the optical waveguide layer 50 and the expansion and contraction in the z direction of the portion of the getter material 60 located on the side surfaces 50B and 50D of the optical waveguide layer 50.

In this way, by applying the getter material 60 not only to the upper surface 53 of the optical waveguide layer 50 but also around the side surfaces 50B and 50D of the optical waveguide layer 50, even if there is a difference in thermal expansion coefficient between the getter material 60 and the optical waveguide layer 50, it is possible to suppress the expansion and contraction of the getter material 60 due to temperature changes in the laser module and prevent misalignment between the center of the entrance of each optical waveguide 51-1, 51-2, 51-3 of the optical waveguide layer 50 and the optical axis of the emitted light from the corresponding laser element 30-1, 30-2, 30-3.

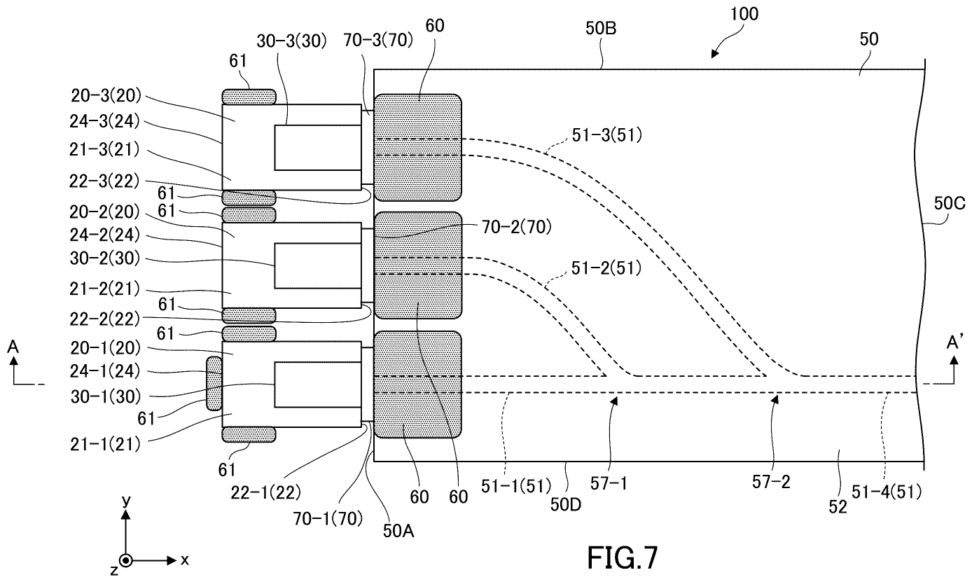

FIG. 7 is a schematic plan view of a portion of a laser assembly showing another arrangement example of the getter material 60.

In the laser assembly 100 of this embodiment, in addition to the getter material 60 on the upper surface 53 of the optical waveguide layer 50, a getter material 61 that adsorbs a substance different from the getter material 60 may be arranged on at least one side surface 23 of the multiple subcarriers 20. It is preferable to use the getter material 61 in a form that can be applied to the side surface 23 of the subcarrier 20 using a dispenser or the like, similar to the getter material 60.

For example, a getter material that adsorbs VOCs may be used as the getter material 60, and a getter material that adsorbs moisture may be used as the getter material 61. Conversely, a getter material that adsorbs moisture may be used as the getter material 60, and a getter material that adsorbs VOCs may be used as the getter material 61. Alternatively, a getter material that adsorbs SiO among the VOCs may be used as the getter material 60, and a getter material that adsorbs hydrocarbons among the VOCs may be used as the getter material 61. Conversely, a getter material that adsorbs hydrocarbons may be used as the getter material 60, and a getter material that adsorbs SiO may be used as the getter material 61.

FIG. 7 shows an example in which the getter material 61 is disposed on both side surfaces 23-1a, 23-1b, 23-2a, 23-2b, 23-3a, and 23-3b of the subcarriers 20-1, 20-2, and 20-3, but the getter material 61 may be disposed only on the subcarrier 20-1 on which the blue laser element 30-1 is mounted, for example. Furthermore, for example, the getter material 61 arranged on one side surface 23-la of the subcarrier 20-1 and the getter material 61 arranged on the other side surface 23-1b may adsorb different substances.

Furthermore, the getter material 61 may also be arranged on the end surface 24 of each subcarrier 20. FIG. 7 shows an example in which the getter material 61 is arranged on the end surface 24-1 of the subcarrier 20-1 on which the blue laser element 30-1 is mounted.

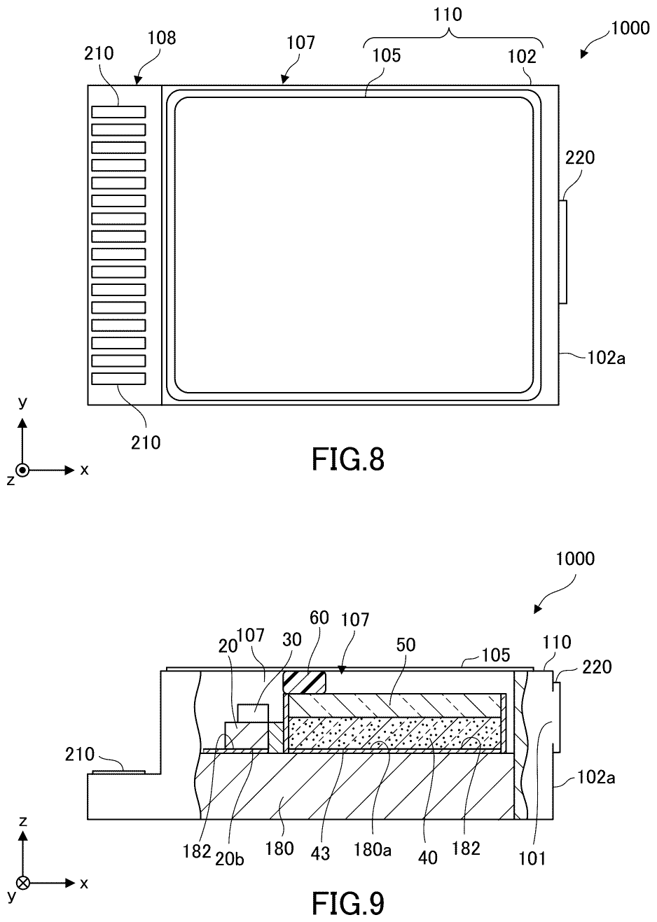

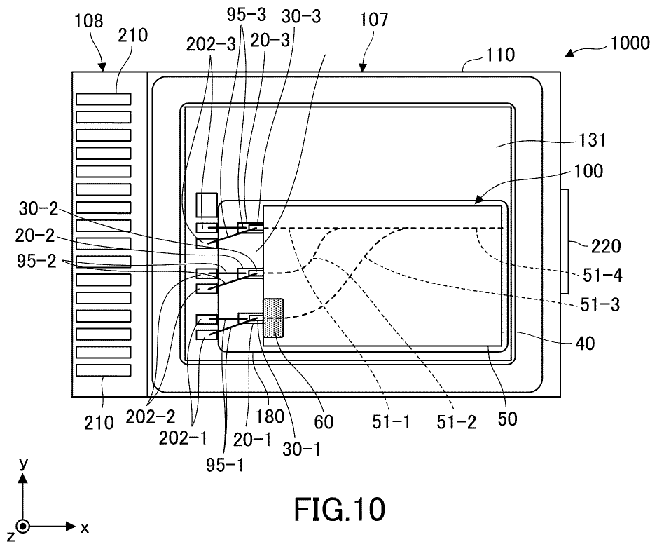

FIG. 8 is a schematic plan view of the laser module of this embodiment. FIG. 9 is a cross-sectional view of a laser assembly arranged inside the laser module shown in FIG. 8, which is cut in the X-Z plane. FIG. 10 is a plan view of the laser module with the cover removed.

The laser module 1000 is housed in a package 110, in which the laser assembly 100 according to the above embodiment is installed on the upper surface 180a of the base 180.

In the laser assembly 100, the subcarrier 20 and the optical waveguide substrate 40 are bonded by metal eutectic bonding, so that the occurrence of positional deviation due to the heating process is significantly suppressed compared to a configuration in which they are bonded by adhesive.

The package 110 may also include known components other than the laser assembly according to the above embodiment. For example, a photodetector (PD) can be housed.

When the laser module 1000 includes a PD, the current flowing through the PD can be observed to check the optical output fluctuation of the laser element. In addition, the current flowing through the PD can be monitored to control the drive current of the laser element so that the output is constant.

The package 110 includes a main body 102 with a cavity structure that houses the laser assembly 100 inside, and a cover 105 that covers the main body 102 from above the optical waveguide layer 50. The main body 102 has a bottom on which the components housed inside are placed, and a sidewall 102a that is arranged to surround the components from the sides.

FIG. 9 shows an example in which the getter material 60 is in contact with the bottom surface of the cover 105 of the package 110. The thickness of the getter material 60 in this case is, for example, 500 μm or more and 1000 μm or less, particularly around 650 μm. When the getter material 60 is in contact with the cover 105 in this way, the heat generated by the laser element 30 can be dissipated through the getter material 60.

A light-transmitting window (opening) 101 through which the laser light emitted from the laser element 30 can optically pass is formed in the side wall 102a of the storage section 107 near the emission section of the laser light emitted from the laser module 1000.

The opening 101 is formed with its center approximately at a position where it intersects with the optical axis of the laser light emitted from the side wall 102a. The opening 101 is tightly covered by a glass plate 220 from the outside of the side wall 102a. In other words, the storage section 107 is hermetically sealed by the glass plate 220 in addition to the cover 105. Here, the glass plate 220 is used for hermetic sealing, but it is not limited to a glass plate as long as it is a material through which the laser light can pass. An anti-reflection film (not shown) may be provided on both surfaces of the glass plate 220.

The electrode section 108 is disposed on the front side of the housing section 107 in the x direction, i.e., on the rear side in the x direction. The upper surface of the electrode section 108 is located lower than the upper surface of the housing section 107. The bottom surface of the electrode section 108 is located at approximately the same height as the bottom surface of the housing section 107. A plurality of external electrode pads 210 are provided on the upper surface of the electrode section 108 at intervals in the y direction.

The bottom surface 43 of the optical waveguide substrate 40 may be bonded to the upper surface 180a (one inner surface) of the base 180 via an adhesive layer 182. This adhesive layer 182 is made of a material in which a filler is mixed into a resin in order to improve thermal conductivity. An example of the resin that constitutes the adhesive layer 182 is epoxy resin. Copper powder, aluminum powder, alumina powder, etc. can be used as a filler that improves the thermal conductivity of the resin.

In order to maintain a certain level of thermal conductivity, the adhesive layer 182 preferably has a thermal conductivity of 0.5 W/m·K or more, more preferably 1 W/m·K or more, and even more preferably 4 W/m·K or more.

As shown in FIG. 10, a plurality of internal electrode pads 202 (202-1, 202-2, 202-3) are provided at intervals in the y direction on the bottom wall portion 131 located between the base 180 below the subcarrier 20 and the external electrode pad 210 in the x direction.

The laser element 30 and each of the subcarrier 20 are connected to the internal electrode pads 202 corresponding to each laser element 30 by wires 95 using a method such as wire bonding. For example, the laser element 30-1 and the subcarrier 20-1 are individually connected to the two internal electrode pads 202-1 by wires 95-1. The laser element 30-2 and the subcarrier 20-2 are individually connected to the two internal electrode pads 202-2 by wires 95-2. The laser element 30-3 and the subcarrier 20-3 are individually connected to the two internal electrode pads 202-3 by wires 95-3.

The internal electrode pads 202-1, 202-2, and 202-3 are each connected to a different external electrode pad 210. As described above, the external electrode pads 210 electrically connected to the internal electrode pads 202-1, 202-2, and 202-3 are electrically connected to a power source (not shown) or the like. That is, in the laser assembly 100, the laser element 30 and a power supply (not shown) are connected by wires 95, internal electrode pads 202-1, 202-2, 202-3, and external electrode pad 210. When power is supplied from a power supply (not shown) to the external electrode pads 210 corresponding to the internal electrode pads 202-1, 202-2, 202-3, blue light, green light, and red light are emitted from the laser elements 30-1, 30-2, 30-3.

The XR glasses according to this embodiment are equipped with the laser module according to the above embodiment. XR glasses (eyeglasses) are glasses-type terminals, and XR is a general term for virtual reality (VR), augmented reality (AR), and mixed reality.

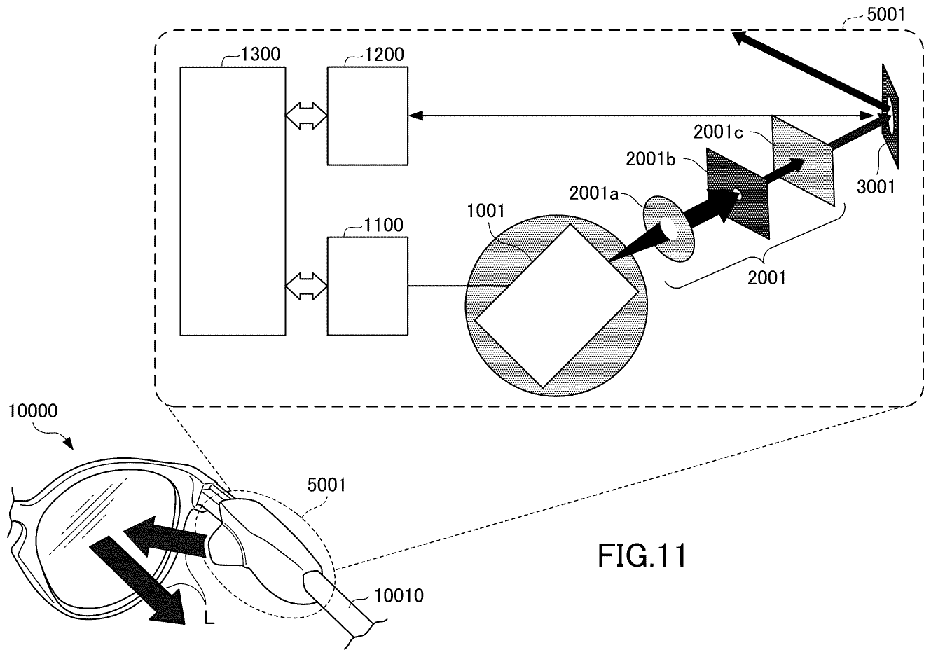

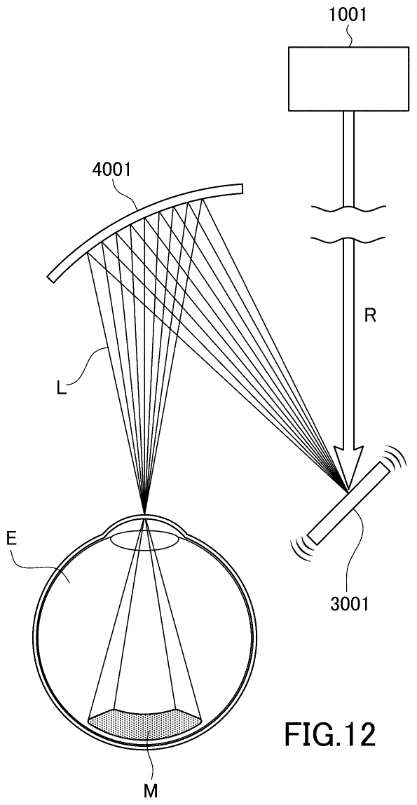

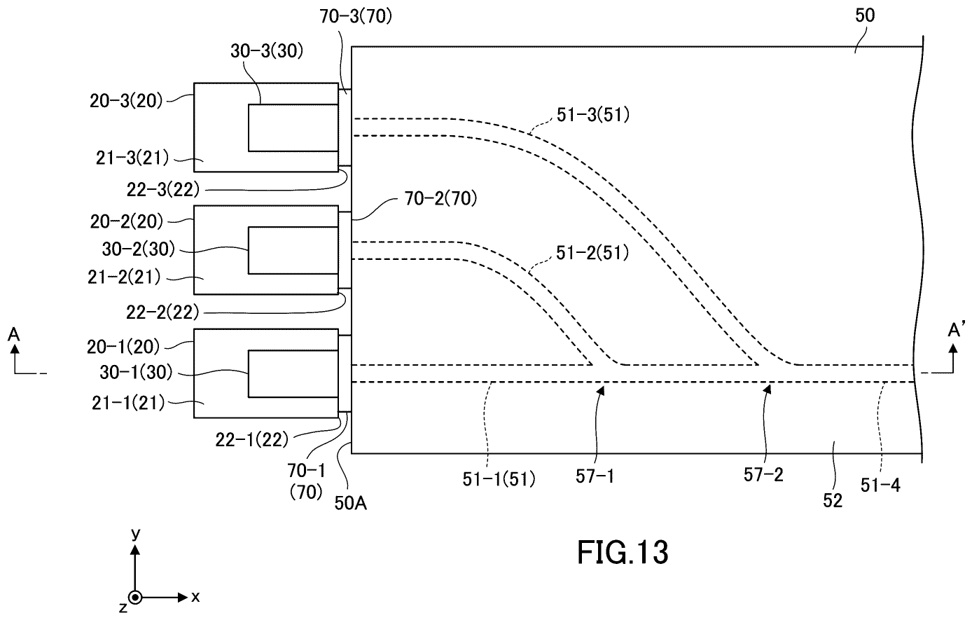

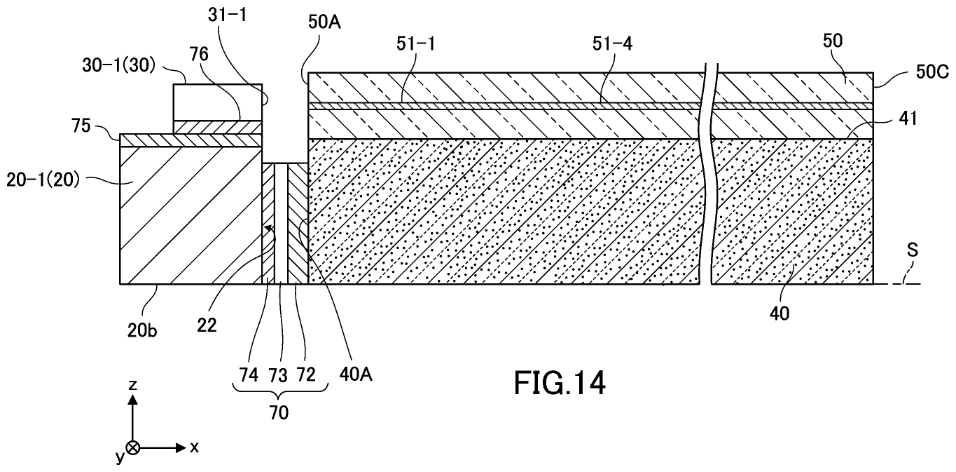

FIG. 11 shows a conceptual diagram for explaining the XR glasses according to this embodiment. The XR glasses 10000 shown in FIG. 11 have a laser module 1001 mounted on an optical engine 5001 provided on a frame 10010. The symbol L is image display light.

In FIG. 11, the laser module 1001, the optical scanning mirror 3001, and the optical system 2001 connecting the laser module 1001 and the optical scanning mirror 3001, which are provided in the XR glasses 10000, are collectively referred to as the optical engine 5001 in this specification. As the laser module 1001, any of the laser modules according to the above embodiments is used.

As the light source in the laser module 1001, for example, one having RGB laser elements of laser element 30-1, laser element 30-2, and laser element 30-3 and a near-infrared laser element can be used.

As shown in FIG. 12, the laser light emitted from the laser module 1001 attached to the eyeglass frame is reflected by the optical scanning mirror 3001, and the reflected light is reflected by the mirror 4001 that reflects it in the direction of the human eyeball E, enters the human eyeball E, and an image (video) can be directly projected onto the retina M.

By providing an eye tracking mechanism, an image can be directly projected onto the retina while performing eye tracking. A publicly known eye tracking mechanism can be used.

The optical scanning mirror 3001 is, for example, a MEMS mirror that scans the laser light emitted from the laser module 1001. To project a 2D image, it is preferable that the mirror be a two-axis MEMS mirror that vibrates to reflect the laser light by changing the angle in the horizontal direction (X direction) and vertical direction (Y direction).

The optical system 2001, which optically processes the laser light emitted from the laser module 1001, has a collimator lens 2001a, a slit 2001b, and an ND filter 2001c. This optical system is an example, and other configurations are also possible.

The optical engine 5001 has a laser driver 1100, an optical scanning mirror driver 1200, and a video controller 1300 that controls these drivers.

### APPENDIX

One aspect of the present disclosure is a laser module, in which the first getter material is disposed individually in front of at least one of the plurality of laser elements on the upper surface of the optical waveguide layer.

One aspect of the present disclosure is a laser module, in which the plurality of laser elements include a blue laser element that emits the blue laser light having a peak wavelength of 380 nm or more and 500 nm or less, and the first getter material is disposed in front of the blue laser element.

One aspect of the present disclosure is a laser module, in which the first getter material is disposed so as to cover a part of the upper surface and a part of the side surface of the optical waveguide layer.

One aspect of the present disclosure is a laser module, in which a second getter material that adsorbs a substance different from the first getter material is disposed on at least one side surface of the plurality of laser element bases.

One aspect of the present disclosure is a laser module, in which the thickness of the first getter material is 100 μm or more and 300 μm or less.

One aspect of the present disclosure is a laser module, in which the package includes a main body that houses therein the plurality of laser element bases on which the plurality of laser elements are installed and the optical waveguide substrate on which the optical waveguide layer is provided, and a cover that covers the main body from above the optical waveguide layer, and the first getter material is in contact with the cover of the package.

Although the disclosure has been described with respect to only a limited number of embodiments, those skilled in the art, having benefit of this disclosure, will appreciate that various other embodiments may be devised without departing from the spirit and scope of the present disclosure. Accordingly, the technical scope of the disclosed subject matter should be limited only by the attached claims.

### DESCRIPTION OF REFERENCE NUMERALS AND SIGNS

20 Subcarrier (laser element base)
21 Main surface
22 Bonding surface
23 Side surface
24 End surface
30-1 Blue laser element (laser element)
30-2 Red laser element (laser element)
30-3 Green laser element (laser element)
40 Optical waveguide substrate
40A Bonding surface
40B, 40D Side surface
41 Main surface
50 Optical waveguide layer
50A Incident surface
50C Emission surface
50B, 50D Side surface
51 Optical waveguide
53 Upper surface
60 Getter material (first getter material)
61 Getter material (second getter material)
100 Laser assembly
102 Main body
105 Cover
110 Package
1000, 1001 Laser module
3001 Optical scanning mirror
5001 Optical engine
10000 XR glasses

What is claimed is:

1. A laser module comprising:
a plurality of laser element bases;
a plurality of laser elements mounted on the respective main surfaces of the plurality of laser element bases; and
an optical waveguide substrate having an optical waveguide layer on its main surface, the optical waveguide layer having an optical waveguide for guiding laser light respectively emitted from the plurality of laser elements;
wherein the plurality of laser element bases, the plurality of laser elements, and the optical waveguide substrate are provided in a package,
wherein a first getter material for adsorbing volatile organic compounds is disposed on the upper surface of the optical waveguide layer in the vicinity of the incident surface of the optical waveguide layer on which the laser light is incident.

2. The laser module according to claim 1,
wherein the first getter material is disposed individually in front of at least one of the plurality of laser elements on the upper surface of the optical waveguide layer.

3. The laser module according to claim 2,
wherein the plurality of laser elements include a blue laser element that emits the blue laser light having a peak wavelength of 380 nm or more and 500 nm or less, and
wherein the first getter material is disposed in front of the blue laser element.

4. The laser module according to claim 3,
wherein the plurality of laser elements further include:
a red laser element that emits the red laser light having a peak wavelength of 630 nm or more and 830 nm or less; and
a green laser element that emits the green laser light having a peak wavelength of 500 nm or more and 550 nm or less.

5. The laser module according to claim 1,
wherein the first getter material is disposed so as to cover a part of the upper surface and a part of the side surface of the optical waveguide layer.

6. The laser module according to claim 1,
wherein a second getter material that adsorbs a substance different from the first getter material is disposed on at least one side surface of the plurality of laser element bases.

7. The laser module according to claim 1,
wherein the thickness of the first getter material is 100 μm or more and 300 μm or less.

8. The laser module according to claim 1,
wherein the package includes a main body that houses therein the plurality of laser element bases on which the plurality of laser elements are installed and the optical waveguide substrate on which the optical waveguide layer is provided, and a cover that covers the main body from above the optical waveguide layer, and
wherein the first getter material is in contact with the cover of the package.

9. The laser module according to claim 8,
wherein the thickness of the first getter material is 500 μm or more and 1000 μm or less.

10. The laser module according to claim 1,
wherein the volatile organic compound is SiO or a hydrocarbon.

11. The laser module according to claim 6,
wherein the first getter material adsorbs the volatile organic compound, and
wherein the second getter material adsorbs moisture.

12. The laser module according to claim 6,
wherein the first getter material adsorbs SiO, and
wherein the second getter material adsorbs hydrocarbons.

13. The laser module according to claim 6,
wherein the first getter material adsorbs hydrocarbons, and
wherein the second getter material adsorbs SiO.

14. The laser module according to claim 1,
wherein the first getter material contains phenol-formaldehyde polymer glycidyl ether.

15. The laser module according to claim 1,
wherein the optical waveguide layer is a PLC (Planar Lightwave Circuit) formed of a glass material.

16. The laser module according to claim 1,
wherein the optical waveguide layer is a PLC formed of a lithium niobate film.

17. The laser module according to claim 1,
wherein the optical waveguide substrate is formed of silicon.

18. The laser module according to claim 16,
wherein the optical waveguide substrate is formed of sapphire, silicon, or thermally oxidized silicon.

19. An optical engine comprising:
a laser module according to claim 1; and
an optical scanning mirror that scans the light emitted from the laser module.

20. XR glasses comprising the optical engine according to claim 19.
